(19) United States
(12) Patent Application Publication
(10) Pub. No.: US 2007/0069216 A1
(43) Pub. Date: Mar. 29, 2007

(54) Substrate for compound semiconductor device and compound semiconductor device using the same

(75) Inventors: Jun Komiyama, Hadano-shi (JP); Yoshihisa Abe, Sagamihara-shi (JP); Shunichi Suzuki, Hadano-shi (JP); Hideo Nakanishi, Hadano-shi (JP)

Correspondence Address: FOLEY AND LARDNER LLP;SUITE 500, 3000 K STREET NW, WASHINGTON, DC, 20007, US

(73) Assignee: TOSHIBA CERAMICS CO., LTD.

(21) Appl. No.: 11/434,115

(22) Filed: May 16, 2006

(30) Foreign Application Priority Data
Sep. 28, 2005 (JP) 2005-281135

(51) Int. Cl. H01L 31/0312

(52) U.S. Cl. 257/77

(57) ABSTRACT

A substrate for compound semiconductor device and a compound semiconductor device using the substrate are provided which allow a breakdown voltage to be high, cause little energy loss, and are suitably used for a high-electron mobility transistor etc. An n-type 3C—SiC single crystal buffer layer 3 having a carrier concentration of 10¹⁶-10²¹/cm³, a hexagonal GaₓAl₁₋ₓN single crystal buffer layer (0≦x<1) 4, an n-type hexagonal Ga_{y}Al_{1-y}N single crystal layer (0.2≦y≦1) 5 having a carrier concentration of 10¹¹-10¹⁶/cm³, and an n-type hexagonal Ga_{z}Al_{1-z}N single crystal carrier supply layer (0≦z≦0.8, and 0.2≦y−z≦1) 6 having a carrier concentration of 10¹¹-10¹⁶/cm³ are stacked in order on an n-type Si single crystal substrate 2 having a crystal-plane orientation {111} and a carrier concentration of 10¹⁶-10²¹/cm³. A back electrode 7 is formed in the back of the above-mentioned substrate 2 and a surface electrode 8 is formed on a surface of the above-mentioned carrier supply layer 6.

### BACKGROUND OF THE INVENTION

1. Field of the Invention

The present invention relates to a compound semiconductor device including 3C—SiC (silicon carbide in cubic crystal form) used for a semiconductor device which allows high frequency and high efficiency, etc., and compound semiconductor single crystal films, such as a nitride represented by GaN (gallium nitride in hexagonal crystal form) and AlN (aluminum nitride in hexagonal crystal form).

2. Description of the Related Art

A compound semiconductor provides an electron transfer rate which is considerably faster than that in silicon, and therefore is suitable for high-speed signal processing and has the property of operating at a low voltage, reacting to light, or emitting a microwave. From such outstanding physical properties, a device using the compound semiconductor is expected to exceed the physical-properties range of a semiconductor silicon device which is currently dominant. However, this type of compound semiconductor is expensive, and there is a demand for reduction in cost. A known example of such a compound semiconductor allowing low cost is one in which a compound semiconductor single crystal buffer layer and a compound semiconductor single crystal film are stacked on a Si single crystal substrate, then a high-electron mobility transistor (HEMT; High Electron Mobility Transistor) device structure is formed by using GaN etc. (for example, see Japanese Laid-open Patent No. 2003-59948).

However, a conventional device fabricated by using such a compound semiconductor, as mentioned above, has a problem in that the conventional device is not devised to remove holes generated at the time of operation of a HEMT device and the device may be broken at a low voltage.

This is because multiple layers of AlN (band gap: 6.2 eV) with a larger band gap than that of GaN (band gap: 3.4 eV) in a device active layer are stacked, and as a result the band gap of AlN is so high that the holes generated in GaN cannot pass over it and AlN is so thick that the hole generated in GaN cannot pass through it, thus AlN is a barrier of the holes and the generated holes are accumulated to break the device.

Further, the HEMT using GaN and formed on the conventional compound semiconductor single crystal buffer layer has a low concentration of a two-dimensional electron gas which occurs in the device active layer.

This is because a difference in a thermal expansion coefficient between the Si single crystal substrate (thermal expansion coefficient: 4.2×10⁻⁶/K) and the compound semiconductor single crystal buffer layer (thermal expansion coefficient: 5.3×10⁻⁶-5.6×10⁻⁶/K) even reaches 18-33%, and stress caused by the difference reduces the concentration of the generated two dimensional electron gas.

There is a problem that a low concentration of the two dimensional electron gas increases resistance when the device is in operation, thus causing energy loss.

### SUMMARY OF THE INVENTION

The present invention is made in order to solve the above-mentioned technical problems, and aims to provide a substrate for compound semiconductor device which allows a breakdown voltage to be high, causes little energy loss, and is suitably used for the high-electron mobility transistor etc., and a compound semiconductor device using the substrate.

A substrate for compound semiconductor device in accordance with the present invention is provided in which at least a 3C—SiC layer having a thickness of 100 nm or more and a high-electron mobility transistor (HEMT) structure are formed on a Si single crystal substrate.

In particular, a substrate for compound semiconductor device of a first preferred embodiment in accordance with the present invention is provided in which an n-type 3C—SiC single crystal buffer layer having a thickness of 0.05-2 μm and a carrier concentration of 10¹⁶-10²¹/cm³, a hexagonal GaₓAl₁₋ₓN single crystal buffer layer having a thickness of 0.01-0.5 μm (0≦x<1), an n-type hexagonal Ga_{y}Al_{1-y}N single crystal layer (0.2≦y≦1) having a thickness of 0.5-5 μm and a carrier concentration of 10¹¹-10¹⁶/cm³, and an n-type hexagonal Ga_{z}Al_{1-z}N single crystal carrier supply layer (0≦z≦0.8, and 0.2≦y−z≦1) having a thickness of 0.01-0.1 μm and a carrier concentration of 10¹¹-10¹⁶/cm³ are stacked in order on an n-type Si single crystal substrate having a crystal-plane orientation {111} and a carrier concentration of 10¹⁶-10²¹/cm³.

Being constructed as mentioned above, the substrate for compound semiconductor device allows a breakdown voltage to be high, causes little energy loss, and therefore can suitably be used for a HEMT for a power device.

As for the substrate for compound semiconductor device in accordance with the above-mentioned first preferred embodiment, it is preferable that an n-type c-BP (cubic boron phosphide) single crystal buffer layer having a thickness of 0.01-1 μm and a carrier concentration of 10¹⁶-10²¹/cm³ is inserted and formed between the Si single crystal substrate and the 3C—SiC single crystal buffer layer.

By means of this c-BP single crystal buffer layer, it is possible to reduce m is fit dislocation in 3C—SiC single crystal buffer layer and improve the concentration of the two dimensional electron gas.

Further, a substrate for compound semiconductor device of a second preferred embodiment in accordance with the present invention is provided in which a p-type 3C—SiC single crystal buffer layer having a thickness of 0.05-2 μm and a carrier concentration of 10¹⁶-10²¹/cm³, a hexagonal GaₓAl₁₋ₓN single crystal buffer Layer (0≦x<1) having a thickness of 0.01-0.5 μm, an n-type hexagonal Ga_{y}Al_{1-y}N single crystal layer (0.2≦y≦1) having a thickness of 0.5-5 μm and a carrier concentration of 10¹¹-10¹⁶/cm³, and an n-type hexagonal Ga_{z}Al_{1-z}N single crystal carrier supply layer (0≦z≦0.8 and 0.2≦y−z≦1) having a thickness of 0.01-0.1 μm and a carrier concentration of 10¹¹-10¹⁶/cm³ are stacked in order on a p-type Si single crystal substrate having a crystal-plane orientation {111} and a carrier concentration 10¹⁶-10²¹/cm³.

Thus, by constructing a lower layer part of the substrate for compound semiconductor device to be a p-type, a graded energy gap is formed between the hexagonal GaₓAl₁₋ₓN single crystal buffer layer and the n-type hexagonal Ga_{y}Al_{1-y}N single crystal layer, and generated holes can be removed efficiently, so that the substrate can also be suitably used for the HEMT for the power device.

As for the substrate for compound semiconductor device in accordance with the above-mentioned second preferred embodiment, similar to that of the above-mentioned first preferred embodiment, it is preferable that a p-type c-BP single crystal buffer layer having a thickness of 0.01-1 μm and a carrier concentration of 10¹⁶-10²¹/cm³ is inserted and formed between the Si single crystal substrate and the 3C—SiC single crystal buffer layer.

Furthermore, a substrate for compound semiconductor device of a third preferred embodiment in accordance with the present invention is provided in which a 3C—SiC single crystal buffer layer having a thickness of 0.05-2 μm and a carrier concentration of 10¹¹-10¹⁶/cm³, a hexagonal GaₓAl₁₋ₓN single crystal buffer layer (0≦x<1) having a thickness of 0.01-0.5 μm, an n-type hexagonal Ga_{y}Al_{1-y}N single crystal layer (0.2≦y≦1) having a thickness of 0.5-5 μm and a carrier concentration of 10¹¹-10¹⁶/cm³, and an n-type hexagonal Ga_{z}Al_{1-z}N single crystal carrier supply layer (0≦z≦0.8 and 0.2≦y−z≦1) having a thickness of 0.01-0.1 μm and a carrier concentration of 10¹¹-10¹⁶/cm³ are stacked in order on a Si single crystal substrate having a crystal-plane orientation {111} and a carrier concentration 10¹¹-10¹⁶/cm³.

Thus, by arranging the carrier concentration of a lower layer part of the substrate for compound semiconductor device to be low, parasitic resistance of the substrate produced when the device is operated at a high frequency is reduced, so that the substrate having such a structure can be suitably used for a HEMT for high frequency.

As for the substrate for compound semiconductor device in accordance with the above-mentioned third preferred embodiment, similar to those of the above-mentioned first and second preferred embodiments, it is preferable that a c-BP single crystal buffer layer having a thickness of 0.01-1 μm and a carrier concentration of 10¹¹-10¹⁶/cm³ is inserted and formed between the Si single crystal substrate and the 3C—SiC single crystal buffer layer.

Further, as for the above-mentioned substrate for compound semiconductor device, it is preferable that the hexagonal GaₓAl₁₋ₓN single crystal buffer layer is AlN in hexagonal crystal form (x=0) and the above-mentioned hexagonal Ga_{y}Al_{1-y}N single crystal layer is GaN in hexagonal crystal form (y=1).

By means of such a structure, it is possible to reduce misfit dislocation, improve the concentration of the two dimensional electron gas, reduce the resistance when the device is in operation, and decrease energy loss.

Furthermore, as for the above-mentioned substrate for compound semiconductor device, it is preferable that an n-type two dimensional electron gas having a carrier concentration of 10¹⁶-10²¹/cm³ is generated between the hexagonal Ga_{y}Al_{1-y}N single crystal layer and the hexagonal Ga_{z}Al_{1-z}N single crystal carrier supply layer.

By generating such a two dimensional electron gas, the resistance when the device is in operation is reduced, thus decreasing energy loss.

Depending on a measurement method, concentration of the two dimensional electron gas could be measured in two dimensional unit. For example, the carrier concentration of 10¹⁶-10²¹/cm³ measures 10¹²-10¹⁴/cm² in terms of two dimensional unit.

Further, the compound semiconductor device in accordance with the present invention is a compound semiconductor device using the above-mentioned substrate for compound semiconductor device, in which a back electrode is formed in the back of the Si single crystal substrate, and a surface electrode is formed on a surface of the hexagonal Ga_{z}Al_{1-z}N single crystal carrier supply layer or at an exposed electrode forming portion of the hexagonal Ga_{y}Al_{1-y}N single crystal layer. The above-mentioned back electrode and the surface electrode are each formed of a metal including at least one of Al, Ti, In, Au, Ni, Pt, Pd, and W, and one or two ohmic electrode and a Schottky electrode or a control electrode are at least formed.

As mentioned above, by using the above-mentioned substrate for compound semiconductor device in accordance with the present invention, and by forming such an electrode, a device is obtained in which the resistance in operation is low and energy loss is reduced to approximately 1/100.

### BRIEF DESCRIPTION OF THE DRAWINGS

FIG. 1 is a sectional view schematically showing a compound semiconductor device in accordance with the following Example 1.

### DESCRIPTION OF THE PREFERRED EMBODIMENTS

Hereafter, the present invention will be described in detail.

A substrate for compound semiconductor device in accordance with the present invention is such that at least a 3C—SiC layer having a thickness of 100 nm or more and a HEMT structure are formed on a Si single crystal substrate.

In particular, a substrate for compound semiconductor device of the first preferred embodiment in accordance with the present invention is such that an n-type 3C—SiC single crystal buffer layer having a thickness of 0.05-2 μm and a carrier concentration of 10¹⁶-10²¹/cm³, a hexagonal GaₓAl₁₋ₓN single crystal buffer layer (0≦x<1) having a thickness of 0.01-0.5 μm, an n-type hexagonal Ga_{y}Al_{1-y}N single crystal layer (0.2≦y≦1) having a thickness of 0.5-5 μm and a carrier concentration of 10¹¹-10¹⁶/cm³, and an n-type hexagonal Ga_{z}Al_{1-z}N single crystal carrier supply layer (0≦z≦0.8, and 0.2≦y−z≦1) having a thickness of 0.01-0.1 μm and a carrier concentration of 10¹¹-10¹⁶/cm³ are stacked in order on an n-type Si single crystal substrate having a crystal-plane orientation {111} and a carrier concentration of 10¹⁶-10²¹/cm³.

In the thus constructed substrate for compound semiconductor, a band gap of GaN is 3.4 eV, while a band gap of 3C—SiC is 2.2 eV. Since a band gap of the 3C—SiC single crystal buffer layer is smaller than that of GaN of a device active layer, holes generated in GaN when the device is in operation pass through 3C—SiC, and therefore are not accumulated.

Further, since the hexagonal GaₓAl₁₋ₓN single crystal buffer layer has a thickness as little as 0.01-0.5 μm, the above-mentioned holes can also pass through the hexagonal GaₓAl₁₋ₓN single crystal buffer layer and therefore are not accumulated. Thus, the breakdown voltage of the device is increased to approximately twice the conventional one.

Furthermore, a thermal expansion coefficient of the 3C—SiC single crystal buffer layer is 4.5×10⁻⁶/K, and is a middle value between the Si single crystal substrate (thermal expansion coefficient: 4.2×10⁻⁶/K) and the hexagonal Ga_{y}Al_{1-y}N single crystal layer (thermal expansion coefficient: 5.3×10⁻⁶-5.6×10⁻⁶/K). A difference in the thermal expansion coefficients between the Si single crystal substrate and the 3C—SiC single crystal buffer layer, and a difference between the hexagonal Ga_{y}Al_{1-y}N single crystal layer and the 3C—SiC single crystal buffer layer are 7-18%, and therefore can be reduced as compared with the differences (18-33%) in thermal expansion coefficients of conventional compound semiconductor single crystal buffer layers.

Thus, stresses resulting from the differences in the thermal expansion coefficients decrease. Corresponding to this, the concentration of the generated two dimensional electron gas is improved, the resistance when the device is in operation can be reduced, and energy loss is decreased to approximately ½ as compared with the conventional one.

Therefore, the substrate for compound semiconductor having such a structure, as mentioned above, can be suitably used for a HEMT for a power device.

As for the Si single crystal substrate in the present invention, not only one that is manufactured by the CZ (Czochralski) method, but also one that is manufactured by the FZ (floating zone) method and one in which a Si single crystal layer is epitaxially grown on the Si single crystal substrate by way of a vapor phase epitaxy (Si epitaxial substrate) can be used.

In addition, epitaxial growth can provide a single crystal layer (epitaxial layer) excellent in crystallinity, and has an advantage that a crystal-plane orientation of the substrate can be followed by the epitaxial layer.

As for the above-mentioned Si single crystal substrate, one that has the crystal-plane orientation {111} is used. Here, by the face orientation {111}, we include a little inclination (approximately ten and several degrees) of the crystal-plane orientation {111} or a crystal-plane orientation of high order plane indices, such as {211}.

Further, as for the above-mentioned Si single crystal substrate, one having a carrier concentration of 10¹⁶-10²¹/cm³ is used.

Where the above-mentioned carrier concentration is less than 10¹⁶/cm³, the Si single crystal substrate has the high resistance, so that the energy loss increases when energized. On the other hand, the higher the carrier concentration is, the better result is achieved, from a viewpoint of energy loss. However, it is physically difficult for the Si single crystal to exceed 10²¹/cm³.

It is preferable that the minimum limit of the carrier concentration of the Si single crystal substrate is 10¹⁷/cm³.

The thickness of the above-mentioned Si single crystal substrate is preferably 100-1000 μm, and more preferably 200-800 μm.

When the thickness of the Si single crystal substrate is less than 100 μm, it results in insufficient mechanical strength. On the other hand, when the above-mentioned thickness exceeds 1000 μm, material costs become high and it cannot be said that effects for the costs can be obtained.

An n-type 3C—SiC single crystal buffer layer is formed on the above-mentioned Si single crystal substrate.

When their conductive types are different, a pn-junction is formed near a boundary between the 3C—SiC single crystal buffer layer and the Si single crystal substrate, increasing the resistance and resulting in the energy loss when energized.

The carrier concentration of the above-mentioned 3C—SiC single crystal buffer layer is arranged to be 10¹⁶-10²¹/cm³.

Where the above-mentioned carrier concentration is less than 10¹⁶/cm³, it has the high resistance, resulting in the energy loss when energized. On the other hand, the higher the above-mentioned carrier concentration is, the better result is achieved, from a viewpoint of energy loss. However, it is physically difficult to exceed 10²¹/cm³.

It is preferable that the minimum limit of the carrier concentration of the 3C—SiC single crystal buffer layer is 10¹⁷/cm³.

Further, the thickness of the above-mentioned 3C—SiC single crystal buffer layer is arranged to be 0.05-2 μm.

When the thickness of the above-mentioned 3C—SiC single crystal buffer layer is less than 0.05 μm, a buffer effect is insufficient. On the other hand, if the above-mentioned thickness exceeds 2 μm, only the material costs are high.

More preferably, the thickness of the 3C—SiC single crystal buffer layer is 0.1-1 μm.

The hexagonal GaₓAl₁₋ₓN single crystal buffer layer (0≦x<1) is formed on the above-mentioned 3C—SiC single crystal buffer layer.

This layer plays the role of a buffer layer on which the hexagonal Ga_{y}Al_{1-y}N single crystal layer is stacked.

A thickness of the above-mentioned hexagonal GaₓAl₁₋ₓN single crystal buffer layer is arranged to be 0.01-0.5 μm.

When the above-mentioned thickness is less than 0.01 μm, a buffer effect of the hexagonal GaₓAl₁₋ₓN single crystal buffer layer is insufficient. On the other hand, if the above-mentioned thickness exceeds 0.5 μm, it has the high resistance, resulting in the energy loss when energized. More preferably the thickness of the above-mentioned hexagonal GaₓAl₁₋ₓN single crystal buffer layer is 0.02-0.1 μm.

Furthermore, an n-type hexagonal Ga_{y}Al_{1-y}N single crystal layer (0.2≦y≦1) is formed on the above-mentioned hexagonal GaₓAl₁₋ₓN single crystal buffer layer.

When conductive types are different, pn-junctions are formed near boundaries of the 3C—SiC single crystal buffer layer, the hexagonal GaₓAl₁₋ₓN single crystal buffer layer, and the hexagonal Ga_{y}Al_{1-y}N single crystal layer, thus increasing the resistance and resulting in the energy loss when energized.

The carrier concentration of the above-mentioned hexagonal Ga_{y}Al_{1-y}N single crystal layer is arranged to be 10¹¹-10¹⁶/cm³.

Although the lower carrier concentration mentioned above provides the better result from a viewpoint of a compound semiconductor performance, it is physically difficult to be less than 10¹¹/cm³. On the other hand, if the above-mentioned carrier concentration exceeds 10¹⁶/cm³, a hexagonal G_{y}Al_{1-y}N single crystal layer suffers from the problem of being destroyed at a low voltage.

Further, the thickness of the above-mentioned hexagonal Ga_{y}Al_{1-y}N single crystal layer is arranged to be 0.1-5 μm.

Where the above-mentioned thickness is less than 0.1 μm, a target device with the high breakdown voltage can not be obtained. On the other hand, if the above-mentioned thickness exceeds 5 μm, only the material costs are high.

More preferably, the thickness of the above-mentioned hexagonal Ga_{y}Al_{1-y}N single crystal layer is 0.5-4 μm.

Furthermore, an n-type hexagonal Ga_{z}Al_{1-z}N single crystal carrier supply layer (0≦z≦0.8 and 0.2≦y−z≦1) is formed on the above-mentioned Ga_{y}Al_{1-y}N single crystal layer.

When their conductive types are different, a pn-junction is formed near a boundary between the hexagonal Ga_{y}Al_{1-y}N single crystal layer and the hexagonal Ga_{z}Al_{1-z}N single crystal carrier supply layer, thus increasing the resistance and resulting in the energy loss when energized.

The carrier concentration of the above-mentioned hexagonal Ga_{z}Al_{1-z}N single crystal carrier supply layer is arranged to be 10¹¹-10¹⁶/cm³.

Although the lower carrier concentration mentioned above provides the better result from a viewpoint of a compound semiconductor performance, it is physically difficult to be less than 10¹¹/cm³. On the other hand, if the above-mentioned carrier concentration exceeds 10¹⁶/cm³, the hexagonal Ga_{z}Al_{1-z}N single crystal carrier supply layer suffers from the problem of being destroyed at a low voltage.

Further, the thickness of the above-mentioned hexagonal Ga_{z}Al_{1-z}N single crystal carrier supply layer is arranged to be 0.01-0.1 μm.

When the above-mentioned thickness is less than 0.01 μm, carrier supply of the hexagonal Ga_{z}Al_{1-z}N single crystal carrier supply layer is not sufficient. On the other hand, when the above-mentioned thickness exceeds 0.1 μm, there is a possibility that the hexagonal Ga_{z}Al_{1-z}N single crystal carrier supply layer may be broken.

More preferably, the thickness of the above-mentioned hexagonal Ga_{z}Al_{1-z}N single crystal carrier supply layer is 0.02-0.05 μm.

As for the above-mentioned hexagonal GaₓAlₗ₋ₓN single crystal buffer layer (0≦x<1), in the case of x=1, it is GaN. Thus an undesirable chemical reaction may take place too much between Ga and Si and its surface is so rough as not to allow the single crystal to grow any further.

More preferably, x in the above-mentioned hexagonal GaₓAl₁₋ₓN single crystal buffer layer is 0.1-0.9.

Further, the above-mentioned hexagonal Ga_{y}Al_{1-y}N single crystal layer (0.2≦y≦1) and the hexagonal Ga_{z}Al_{1-z}N single crystal carrier supply layer (0≦z≦0.8 and 0.2≦y−z≦1) are subjected to hetero combination, respectively as different types of compound semiconductor single crystals, so that the two dimensional electron gas may be generated near the hetero combination and HEMT performances can be improved. Thus, concentrations of gallium, aluminum, and nitrogen in each layer, i.e., the values of y and z are arranged to be within the above-defined ranges.

Further, in the above-mentioned substrate for compound semiconductor device, it is preferable that the c-BP single crystal buffer layer is inserted and formed between the above-mentioned Si single crystal substrate and the 3C—SiC single crystal buffer layer.

By inserting this c-BP single crystal buffer layer, it is possible to reduce the misfit dislocation in the 3C—SiC single crystal buffer layer, to thereby improve the concentration of the above-mentioned two dimensional electron gas.

Therefore, the resistance when the device is in operation can be reduced and energy loss can be decreased to approximately ½ as compared with the conventional one.

The above-mentioned c-BP single crystal buffer layer is arranged to have an n-type which is the same conductive type as that of the 3C—SiC single crystal buffer layer.

When their conductive types are different, a pn junction is formed near a boundary of the 3C—SiC single crystal buffer layer, thus increasing the resistance and causing energy loss when energized.

Further, it is preferable that the carrier concentration of the above-mentioned c-BP single crystal buffer layer is 10¹⁶-10²¹/cm³.

Where the above-mentioned carrier concentration is less than 10¹⁶/cm³, it has the high resistance, resulting in the energy loss when energized. On the other hand, the higher the above-mentioned carrier concentration is, the better result is achieved, from a viewpoint of energy loss. However, it is physically difficult to exceed 10²¹/cm³.

It is preferable that the minimum limit of the carrier concentration of the above-mentioned c-BP single crystal buffer layer is 10¹⁷/cm³.

Further, it is preferable that the thickness of the above-mentioned c-BP single crystal buffer layer is 0.01-1 μm.

When the above-mentioned thickness is less than 0.01 μm, a buffer effect and a resistance reduction effect of the c-BP single crystal buffer layer are not sufficient. On the other hand, if the above-mentioned thickness exceeds 0.5 μm, only material costs are high.

Further, the substrate for compound semiconductor device of the second preferred embodiment in accordance with the present invention is such that a p-type 3C—SiC single crystal buffer layer having a thickness of 0.05-2 μm and a carrier concentration of 10¹⁶-10²¹/cm³, a hexagonal GaₓAl₁₋ₓN single crystal buffer layer having a thickness of 0.01-0.5 μm (0≦x<1), an n-type hexagonal Ga_{y}Al_{1-y}N single crystal layer (0.2≦y≦1) having a thickness of 0.5-5 μm and a carrier concentration of 10¹¹-10¹⁶/cm³, and an n-type hexagonal Ga_{z}Al_{1-z}N single crystal carrier supply layer (0≦z≦0.8 and 0.2≦y−z≦1) having a thickness of 0.01-0.1 μm and a carrier concentration of 10¹¹-10¹⁶/cm³ are stacked in order on a p-type Si single crystal substrate having a crystal-plane orientation {111} and a carrier concentration 10¹⁶-10²¹/cm³.

In other words, as for this substrate, p-types are employed as conductive types of the Si single crystal substrate and the 3C—SiC single crystal buffer layer in the substrate for compound semiconductor device of the above-mentioned first preferred embodiment.

In this way, by employing the p-type for the lower layer part of the substrate for compound semiconductor device, and by forming a graded energy gap between the hexagonal GaₓAl₁₋ₓN single crystal buffer layer and the n-type hexagonal Ga_{y}Al_{1-y}N single crystal layer, generated holes can be drawn out efficiently, and the holes are not accumulated. Thus, the breakdown voltage of the device is increased to approximately twice the conventional one.

Therefore, the substrate for compound semiconductor device having such a structure can be suitably used for a HEMT for a power device.

Also for the substrate for compound semiconductor device in accordance with the above-mentioned second preferred embodiment, similar to that of the above-mentioned first preferred embodiment, it is preferable that a p-type c-BP single crystal buffer layer having a thickness of 0.01-1 μm and a carrier concentration of 10¹⁶-10²¹/cm³ is inserted and formed between the Si single crystal substrate and the 3C—SiC single crystal buffer layer, in conjunction with the conductive type of these layers.

Further, the substrate for compound semiconductor device of the third preferred embodiment in accordance with the present invention is such that a 3C—SiC single crystal buffer layer having a thickness of 0.05-2 μm and a carrier concentration of 10¹¹-10¹⁶/cm³, a hexagonal GaₓAl₁₋ₓN single crystal buffer layer having a thickness of 0.01-0.5 μm (0≦x<1), an n-type hexagonal Ga_{y}Al_{1-y}N single crystal layer (0.2≦y≦1) having a thickness of 0.5-5 μm and a carrier concentration of 10¹¹-10¹⁶/cm³, and an n-type hexagonal Ga_{z}Al_{1-z}N single crystal carrier supply layer (0≦z≦0.8 and 0.2≦y−z≦1) having a thickness of 0.01-0.1 μm and a carrier concentration of 10¹¹-10¹⁶/cm³ are stacked in order on a Si single crystal substrate having a crystal-plane orientation {111} and a carrier concentration 10¹¹-10¹⁶/cm³.

In other words, this substrate employs a low carrier concentration for the Si single crystal substrate and the 3C—SiC single crystal buffer layer in the substrate for compound semiconductor device of the above-mentioned first preferred embodiment. A sufficient reduction in the carrier concentration is important for a high frequency use, and either p or n-type may be used.

In addition, when the carrier concentration is sufficiently reduced, it is difficult to determine the conductive type in practical use.

Thus, by arranging the carrier concentration of a lower layer part of the substrate for compound semiconductor device to be low, parasitic resistance of the substrate produced when the device is operated at a high frequency is reduced, and energy resistance is decreased to approximately to 1/100 as compared with a conventional one. Therefore the substrate for compound semiconductor device having such a structure can be suitably used for a HEMT for high frequency.

Also in the substrate for compound semiconductor device of the above-mentioned third preferred embodiment, as with the above-mentioned first and second preferred embodiments, it is preferable that the c-BP single crystal buffer layer having the above-mentioned thickness of 0.01-1 μm the carrier concentration of 10¹¹-10¹⁶/cm³ is inserted and formed between the Si single crystal substrate and the 3C—SiC single crystal buffer layer, in conjunction with the carrier concentration of these layers.

Further, also in the substrate for compound semiconductor device in accordance with any of the first to third preferred embodiments, it is preferable that the hexagonal GaₓAl₁₋ₓN single crystal buffer layer is AlN in hexagonal crystal form (x=0) and the hexagonal Ga_{y}AL_{1-y}N single crystal layer is GaN in hexagonal crystal form (y=1).

In this case, lattice constants of the 3C—SiC single crystal buffer layer, the hexagonal GaₓAl₁₋ₓN single crystal buffer layer (AlN in hexagonal crystal form (x=0)), and the hexagonal Ga_{y}Al_{1-y}N single crystal layer (GaN in hexagonal crystal form (y=1)) are respectively 3.083 angstrom (a-axis conversion), 3.112 angstrom, and 3.18 angstrom, and degrees of lattice mismatch are small and change gradually, so that misfit dislocation generated due to the lattice mismatch is reduced.

The misfit dislocation allows the two dimensional electron gas to be absorbed, and reduces the concentration. Thus, by reducing the misfit dislocation, the concentration of the two dimensional electron gas is improved, the resistance when the device is in operation is reduced, and energy loss is decreased.

Therefore, the energy loss of the device can be reduced to approximately ½ as compared with a conventional one.

Furthermore, also in the substrate for compound semiconductor device in accordance with any of the above-mentioned first to third preferred embodiments, it is preferable that an n-type two dimensional electron gas having a carrier concentration of 10¹⁶-10²¹/cm³ is generated between the hexagonal Ga_{y}Al_{1-y}N single crystal layer and the hexagonal Ga_{z}Al_{1-z}N single crystal carrier supply layer.

Thus, the resistance when the device is in operation can be reduced, and the energy loss can be decreased to approximately ½ to 1/1000 as compared with a conventional one.

The compound semiconductor device in accordance with the present invention can be fabricated in such a way that a back electrode is formed in the back of the Si single crystal substrate by using the substrate for compound semiconductor device in accordance with the present invention as mentioned above, a surface electrode is formed on a surface of the hexagonal Ga_{z}Al_{1-z}N single crystal carrier supply layer or at an exposed electrode forming portion of the hexagonal Ga_{y}Al_{1-y}N single crystal layer, the above-mentioned back electrode and surface electrode are each formed of a metal including at least one of Al, Ti, In, Au, Ni, Pt, Pd, and W, and one or two ohmic electrode and a Schottky electrode or a control electrode are at least formed.

Such a device has the low resistance when in operation and reduces the energy loss to approximately 1/100 as compared with a conventional one.

### EXAMPLES

Hereafter, the present invention will be described more particularly based on Example, however, the present invention is not limited to the following Example.

### Example 1

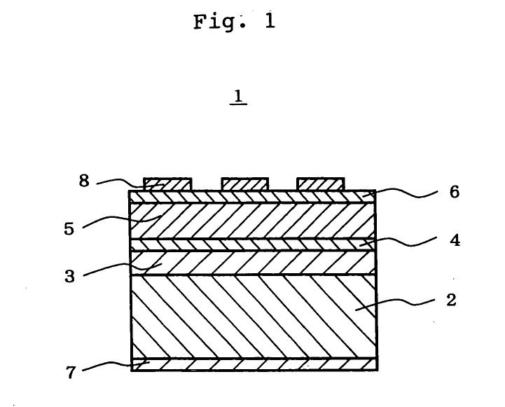

FIG. 1 shows a schematic sectional view of a compound semiconductor device in accordance with this Example.

The compound semiconductor device 1 as shown in FIG. 1 is such that an n-type 3C—SiC single crystal buffer layer 3 having a thickness of 1 μm, a carrier concentration of 10¹⁷/cm³, AlN in hexagonal crystal form (x=0) having a thickness of 0.02 μm as a hexagonal GaₓAl₁₋ₓN single crystal buffer layer 4, GaN in hexagonal crystal form (y=1) having a thickness of 4 μm and a carrier concentration of 10¹⁵/cm³ as an n-type hexagonal Ga_{y}Al_{1-y}N single crystal layer 5, and an n-type hexagonal Ga_{z}Al_{1-z}N single crystal carrier supply layer (z=0.2) 6 are stacked in order on an n-type Si single crystal substrate 2 having a crystal-plane orientation {111}, a carrier concentration of 10¹⁷/cm³, and a thickness of 400 μm, as well as a back electrode 7 and a surface electrode 8 are respectively formed in the back of the Si single crystal substrate 2 and on a surface of the hexagonal Ga_{z}Al_{1-z}N single crystal carrier supply layer (z=0.2) 6.

Hereafter, a manufacturing process of this compound semiconductor device 1 will be described.

Firstly, an n-type Si single crystal substrate 2 having a crystal-plane orientation {111}, a carrier concentration of 10¹⁷/cm³, and a thickness of 400 μm, and manufactured by the CZ method was heat-treated at 1000° C. in a hydrogen atmosphere, and its surface was cleaned.

The above-mentioned Si single crystal substrate 2 was heat-treated at 1000° C. in a C₃H₈ source-gas atmosphere, and an n-type 3C—SiC single crystal buffer layer 3 having a thickness of 10 nm and a carrier concentration of 10¹⁷/cm³ was formed.

Then, by using SiH₄ gas and C₃H₈ gas as a source gas, and by way of 1000° C. vapor phase epitaxy, an n-type 3C—SiC single crystal buffer layer 3 having a thickness of 1 μm and a carrier concentration of 10¹⁷/cm³ was further stacked on the above-mentioned 3C—SiC single crystal buffer layer 3, so as to obtain a desired thickness.

In addition, the thickness of the 3C—SiC single crystal buffer layer 3 was adjusted according to a flow rate and time of the source gas. Further, the carrier concentration was adjusted by adding N₂ as a dopant during the vapor phase epitaxy.

Next, by using TMA (trimethyl aluminium) gas and NH₃ gas as the source gas, and by way of 1000° C. vapor phase epitaxy, AlN in hexagonal crystal form (x=0) as the hexagonal GaₓAl₁₋ₓN single crystal buffer layer 4 having a thickness of 0.02 μm was stacked on the above-mentioned 3C—SiC single crystal layer buffer layer 3.

Further, by using TMG gas and NH₃ gas as the source gas, and by way of 1000° C. vapor phase epitaxy, GaN in hexagonal crystal form (y=1) as the n-type hexagonal Ga_{y}Al_{1-y}N single crystal layer 5 having a thickness of 4 μm and a carrier concentration of 10¹⁵/cm³ was stacked on the hexagonal AlN single crystal buffer layer 4.

Furthermore, by using TMA gas, TMG (trimethyl gallium) gas, and NH₃ gas as the source gas, and by way of 1000° C. vapor phase epitaxy, then-type hexagonal Ga_{z}Al_{1-z}N single crystal layer (z=0.2) 6 having a thickness of 0.02 μm and a carrier concentration of 10¹⁵/cm³ was stacked on the hexagonal GaN single crystal layer 5.

In addition, the thicknesses of the hexagonal AlN single crystal buffer layer 4, the hexagonal GaN single crystal layer 5, and the hexagonal Ga_{0.2}Al_{0.8}N single crystal layer 6 were adjusted according to a material flow rate and time. Further, the carrier concentration was adjusted to be low by not adding the dopant during the heat treatment.

Finally, the back electrode 7 was formed by way of the vacuum deposition of Al, and the surface electrode 8 was formed by way of vacuum deposition of Ni. The ohmic electrode, the Schottky electrode, and the control electrode were adjusted by way of heat treatment.

As for compound semiconductor device 1 obtained by way of the above-mentioned manufacturing process, resistance and breakdown voltage were measured. The resistance was reduced to approximately 1/100 of that of a conventional one and the breakdown voltage was increased to approximately twice that of the conventional one, thus it was used in practice sufficiently.

As described above, according to the present invention, the substrate for semiconductor compound device and the compound semiconductor device are provided which allow little energy loss and high breakdown voltage.

Therefore, the substrate for semiconductor compound devices in accordance with the present invention can be suitably used for a power device, a HEMT for high frequency devices, etc.

1. A substrate for compound semiconductor device in which at least a 3C—SiC layer having a thickness of 100 nm or more and a high-electron mobility transistor structure are formed on a Si single crystal substrate.

2. A substrate for compound semiconductor device in which an n-type 3C—SiC single crystal buffer layer having a thickness of 0.05-2 μm and a carrier concentration of 10¹⁶-10²¹/cm³, a hexagonal GaₓAl₁₋ₓN single crystal buffer layer having a thickness of 0.01-0.5 μm (0≦x<1), an n-type hexagonal Ga_{y}Al_{1-y}N single crystal layer (0.2≦y≦1) having a thickness of 0.5-5 μm and a carrier concentration of 10¹¹-10¹⁶/cm³, and an n-type hexagonal Ga_{z}Al_{1-z}N single crystal carrier supply layer (0≦z≦0.8, and 0.2≦y−z≦1) having a thickness of 0.01-0.1 μm and a carrier concentration of 10¹¹-10¹⁶/cm³ are stacked in order on an n-type Si single crystal substrate having a crystal-plane orientation {111} and a carrier concentration of 10¹⁶-10²¹/cm³.

3. The substrate for compound semiconductor device as claimed in claim 2, wherein an n-type c-BP single crystal buffer layer having a thickness of 0.01-1 μm, and a carrier concentration of 10¹⁶-10²¹/cm³ is inserted and formed between said Si single crystal substrate and 3C—SiC single crystal buffer layer.

4. A substrate for compound semiconductor device in which a p-type 3C—SiC single crystal buffer layer having a thickness of 0.05-2 μm and a carrier concentration of 10¹⁶-10²¹/cm³, a hexagonal GaₓAl₁₋ₓN single crystal buffer layer having a thickness of 0.01-0.5 μm (0≦x<1), an n-type hexagonal Ga_{y}Al_{1-y}N single crystal layer (0.2≦y≦1) having a thickness of 0.5-5 μm and a carrier concentration of 10¹¹-10¹⁶/cm³, and an n-type hexagonal Ga_{z}Al_{1-z}N single crystal carrier supply layer (0≦z≦0.8 and 0.2≦y−z≦1) having a thickness of 0.01-0.1 μm and a carrier concentration of 10¹¹-10¹⁶/cm³ are stacked in order on a p-type Si single crystal substrate having a crystal-plane orientation {111} and a carrier concentration 10¹⁶-10²¹/cm³.

5. The substrate for compound semiconductor device as claimed in claim 4, wherein a p-type c-BP single crystal buffer layer having a thickness of 0.01-1 μm and a carrier concentration of 10¹⁶-10²¹/cm³ is inserted and formed between said Si single crystal substrate and 3C—SiC single crystal buffer layer.

6. A substrate for compound semiconductor device in which a 3C—SiC single crystal buffer layer having a thickness of 0.05-2 μm and a carrier concentration of 10¹¹-10¹⁶/cm³, a hexagonal GaₓAl₁₋ₓN single crystal buffer layer having a thickness of 0.01-0.5 μm (0≦x<1), an n-type hexagonal Ga_{y}Al_{1-y}N single crystal layer (0.2≦y≦1) having a thickness of 0.5-5 μm and a carrier concentration of 10¹¹-10¹⁶/cm³, and an n-type hexagonal Ga_{z}Al_{1-z}N single crystal carrier supply layer (0≦z≦0.8 and 0.2≦y−z≦1) having a thickness of 0.01-0.1 μm and a carrier concentration of 10¹¹-10¹⁶/cm³ are stacked in order on a Si single crystal substrate having a crystal-plane orientation {111} and a carrier concentration 10¹¹-10¹⁶/cm³.

7. The substrate for compound semiconductor device as claimed in claim 6, wherein a c-BP single crystal buffer layer having a thickness of 0.01-1 μm and a carrier concentration of 10¹¹-10¹⁶/cm³ is inserted and formed between said Si single crystal substrate and 3C—SiC single crystal buffer layer.

8. The substrate for compound semiconductor device as claimed in claim 2, wherein said hexagonal GaₓAl₁₋ₓN single crystal buffer layer is AlN in hexagonal crystal form (x=0) and said hexagonal Ga_{y}Al_{1-y}N single crystal layer is GaN in hexagonal crystal form (y=1).

9. The substrate for compound semiconductor device as claimed in claim 2, wherein an n-type two dimensional electron gas having a carrier concentration of 10¹⁶-10²¹/cm³ is generated between said hexagonal Ga_{y}Al_{1-y}N single crystal layer and hexagonal Ga_{z}Al_{1-z}N single crystal carrier supply layer.

10. A compound semiconductor device using the substrate for compound semiconductor device as claimed in claim 1, wherein a back electrode is formed in the back of said Si single crystal substrate, a surface electrode is formed on a surface of said hexagonal Ga_{z}Al_{1-z}N single crystal carrier supply layer or at an exposed electrode forming portion of the hexagonal Ga_{y}Al_{1-y}N single crystal layer, said back electrode and surface electrode are each formed of a metal including as least one of Al, Ti, In, Au, Ni, Pt, Pd, and W, and one or two ohmic electrode and a Schottky electrode or a control electrode are at least formed.
